(19) United States
(12) Patent Application Publication
(10) Pub. No.: US 2015/0155524 A1
(43) Pub. Date: Jun. 4, 2015

(54) WHITE ORGANIC LIGHT EMITTING DEVICE

(71) Applicant: SHENZHEN CHINA STAR OPTOELECTRONICS TECHNOLOGY CO., LTD., Shenzhen, Guangdong (CN)

(72) Inventor: Chih-Che Liu, Shenzhen (CN)

(73) Assignee: SHENZHEN CHINA STAR OPTOELECTRONICS TECHNOLOGY CO., LTD., Shenzhen, Guangdong (CN)

(21) Appl. No.: 14/115,381

(22) PCT Filed: Jun. 28, 2013
(86) PCT No.: PCT/CN2013/078336

§ 371 Date: Nov. 4, 2013

(30) Foreign Application Priority Data
May 6, 2013 (CN) 201310163152.9

(51) Int. Cl. H01L 51/52; H01L 51/00

(52) U.S. Cl. CPC H01L 51/5262; H01L 51/0096; H01L 2251/558; H01L 2251/306; H01L 2251/308

(57) ABSTRACT

The present invention provides a white organic light-emitting device having a substrate, an organic light-emitting unit and an efficiency-enhancing layer. The organic light-emitting unit has a first electrode, a second electrode and an organic layer. The first electrode is disposed on the substrate. The second electrode is disposed opposite to the first electrode. The organic layer is disposed between the first electrode and the second electrode. The efficiency-enhancing layer is disposed on a light-emitting surface of the organic light-emitting unit. The efficiency-enhancing layer can effectively adjust the chromaticity coordinates value and improve light efficiency of the white organic light-emitting device so that directly adjusting the internal structure of the organic light-emitting unit can be avoid.

### FIELD OF THE INVENTION

The present invention relates to a light-emitting device for display device, and more particularly to a white organic light-emitting device.

### BACKGROUND OF THE INVENTION

Nowadays, in flat-panel display industry, the resolution required for AMOLED display panels is steadily increasing, and demand for large-sized AMOLED display panels is also increasing. In order to achieve the foregoing requirement, a kind of display device using white organic light-emitting devices with a color filter is being developed. However, one of the difficult points for implementing this technology is that the white organic light-emitting device is unable to reach the same level of efficiency as a traditional monochromatic organic light-emitting device does. Meanwhile, when manufacturing a white organic light-emitting device, two or three forms of phosphors will be mixed inside the device, thus the internal structure of the device is relatively more complicated. In the condition of using the traditional monochromatic organic light-emitting devices as a light-emitting source, the manufacturer can easily adjust the thickness of layers or structures to enhance device performance. In contrast, in the case of using a white organic light-emitting device as the light source, because the device has a more complex internal structure, adjusting the structure for enhancing performance is more difficult or the adjustment has to be done by forming an optical micro-cavity with a complex reflection structure. Besides, because the white organic light-emitting device has a complex structure, the error tolerant capability of the manufacturing technology for white organic light-emitting devices is relatively limited, thus yield rate is not easy to improve and the cost is relatively high.

Hence, it is necessary to provide a white organic light-emitting device to overcome the problems existing in the conventional technology.

### SUMMARY OF THE INVENTION

In view of the shortcoming of the conventional technology, a primary object of the invention is to provide a white organic light-emitting device with ideal chromaticity coordinates value and better light efficiency.

To achieve the above object, the present invention provides a white organic light-emitting device having: a substrate; an organic light-emitting unit having a first electrode, a second electrode, an organic layer and a light-emitting surface, wherein the first electrode is disposed on the substrate, the second electrode is disposed opposite to the first electrode, the organic layer is mounted between the first electrode and the second electrode; and an efficiency-enhancing layer being mounted on the light-emitting surface of the organic light-emitting unit.

In one embodiment of the present invention, the first electrode is an anode, the second electrode is a cathode, the light-emitting surface of the organic light-emitting unit is located at the first electrode, and the efficiency-enhancing layer is disposed between the first electrode and the substrate.

In one embodiment of the present invention, the first electrode is an anode; the second electrode is a cathode; the light-emitting surface of the organic light-emitting unit is located at the second electrode, and the efficiency-enhancing layer is disposed on the second electrode.

In one embodiment of the present invention, the efficiency-enhancing layer includes at least one silicon dioxide layer and at least one silicon nitride layer.

In one embodiment of the present invention, the efficiency-enhancing layer is constructed by orderly laminating a first silicon dioxide layer, a first silicon nitride layer, a second silicon dioxide layer and a second silicon nitride layer on the substrate.

In one embodiment of the present invention, the efficiency-enhancing layer is constructed by orderly laminating an indium tin oxide layer, a first silicon dioxide layer, a first silicon nitride layer and a second silicon dioxide layer on the substrate.

In one embodiment of the present invention, each of the layers that construct the efficiency-enhancing layer has a thickness less than or equal to 1 micrometer.

In one embodiment of the present invention, the first silicon dioxide layer has a thickness of 100 nanometers, the first silicon nitride layer has a thickness of 30 nanometers, the second silicon dioxide layer has a thickness of 1 nanometer, and the second silicon nitride layer has a thickness of 32 nanometers.

In one embodiment of the present invention, the indium tin oxide layer has a thickness of 10 nanometers, the first silicon dioxide layer has a thickness of 100 nanometers, the silicon nitride layer has a thickness of 30 nanometers, and the second silicon dioxide layer has a thickness of 6 nanometers.

In one embodiment of the present invention, the substrate is a glass substrate.

The present invention further provides a white organic light-emitting device having: a substrate; an organic light-emitting unit having a first electrode, a second electrode, an organic layer and a light-emitting surface, wherein the first electrode is disposed on the substrate and is an anode, the second electrode is disposed opposite to the first electrode and is a cathode, the organic layer is mounted between the first electrode and the second electrode, and the light-emitting surface is located at the first electrode; and an efficiency-enhancing layer being mounted on the light-emitting surface of the organic light-emitting unit, wherein the efficiency-enhancing layer is disposed between the first electrode and the substrate; and the efficiency-enhancing layer is constructed by orderly laminating a first silicon dioxide layer, a first silicon nitride layer, a second silicon dioxide layer and a second silicon nitride layer on the substrate.

In one embodiment of the present invention, each of the first silicon dioxide layer, the first silicon nitride layer, the second silicon dioxide layer and the second silicon nitride layer that construct the efficiency-enhancing layer has a thickness less than or equal to 1 micrometer.

The present invention is implemented by disposing an efficiency-enhancing layer on the light-emitting surface of an organic light-emitting unit so as to improve the efficiency of a white organic light-emitting device, and an objective of easily adjusting the efficiency of the white organic light-emitting device can be achieved by adjusting the thickness of the efficiency-enhancing layer.

### DESCRIPTION OF THE DRAWINGS

FIG. 1 is a schematic view of the structure of a white organic light-emitting device according to a first embodiment of the present invention;

FIG. 2 is a schematic view of the structure of a white organic light-emitting device according to a second embodiment of the present invention;

FIG. 3 is a schematic view of the structure of a white organic light-emitting device according to a third embodiment of the present invention;

FIG. 4 is a chart comparing the efficiency of the white organic light-emitting device of the first embodiment in FIG. 1 with the efficiency of a conventional white organic light-emitting device; and

FIG. 5 is a chart comparing the efficiency of the white organic light-emitting device of the first embodiment in FIG. 2 with the efficiency of a conventional white organic light-emitting device.

### DETAILED DESCRIPTION OF THE PREFERRED EMBODIMENTS

The foregoing objects, features and advantages adopted by the present invention can be best understood by referring to the following detailed description of the preferred embodiments and the accompanying drawings. Furthermore, the directional terms described in the present invention, such as upper, lower, front, rear, left, right, inner, outer, side and etc., are only directions referring to the accompanying drawings, so that the used directional terms are used to describe and understand the present invention, but the present invention is not limited thereto.

With reference to FIG. 1, FIG. 1 is a schematic view of the structure of a white organic light-emitting device according to a first embodiment of the present invention. The white organic light-emitting device mainly comprises a substrate 10, an organic light-emitting unit 11 and an efficiency-enhancing layer 12.

The substrate 10 is a transparent substrate, such as a glass substrate.

The organic light-emitting unit 11 includes a first electrode 110, a second electrode 111 and an organic layer 112. The first electrode 110 is disposed on the substrate 10 and may be an indium tin oxide layer. The second electrode 111 is disposed opposite to the first electrode 110. The organic layer 112 is disposed between the first electrode 110 and the second electrode 111. As shown in FIG. 1, in this embodiment, the first electrode 110 is an anode, and the second electrode 111 is a cathode. The organic light-emitting unit 11 has a light-emitting direction that is from the second electrode 111 to the first electrode 110. The organic layer 112 may be constituted of an electron transport layer, at least two organic light-emitting layers with different colors and a hole transport layer.

The efficiency-enhancing layer 12 is disposed on an light-emitting surface 1100 of the organic light-emitting unit 11. With reference to FIG. 1, because the light-emitting direction of the organic light-emitting unit 11 is from the second electrode 111 to the first electrode 110, the light-emitting surface 1100 of the organic light-emitting unit 11 is located at a surface of the first electrode 110, and therefore the efficiency-enhancing layer 12 is disposed between the first electrode 110 and the substrate 10. The efficiency-enhancing layer 12 is constituted of one or more material layers, wherein each material layer may be an organic material layer, an inorganic material layer or a metallic material (for example, indium tin oxide), and is not limited to one specific stacking order. The efficiency-enhancing layer 12 is used to adjust the characteristics and efficiency of the emitted light from the organic light-emitting unit 11. In this embodiment, the efficiency-enhancing layer 12 includes at least one silicon dioxide (SiO2) layer and at least one silicon dioxide (SiNx) layer, and each of the layers that construct the efficiency-enhancing layer 12 may preferably have a thickness less than or equal to 1 micrometer.

In more details, with reference to FIG. 1, the efficiency-enhancing layer 12 is constructed by orderly laminating a first silicon dioxide layer 120, a first silicon nitride layer 121, a second silicon dioxide layer 122 and a second silicon nitride layer 123 on the substrate 10 from bottom to top, wherein the first silicon dioxide layer 120 may for example have a thickness of 100 nanometers, the first silicon nitride layer 121 may for example have a thickness of 30 nanometers, the second silicon dioxide layer 122 may for example have a thickness of 1 nanometer, and the second silicon nitride layer 123 may for example have a thickness of 32 nanometers.

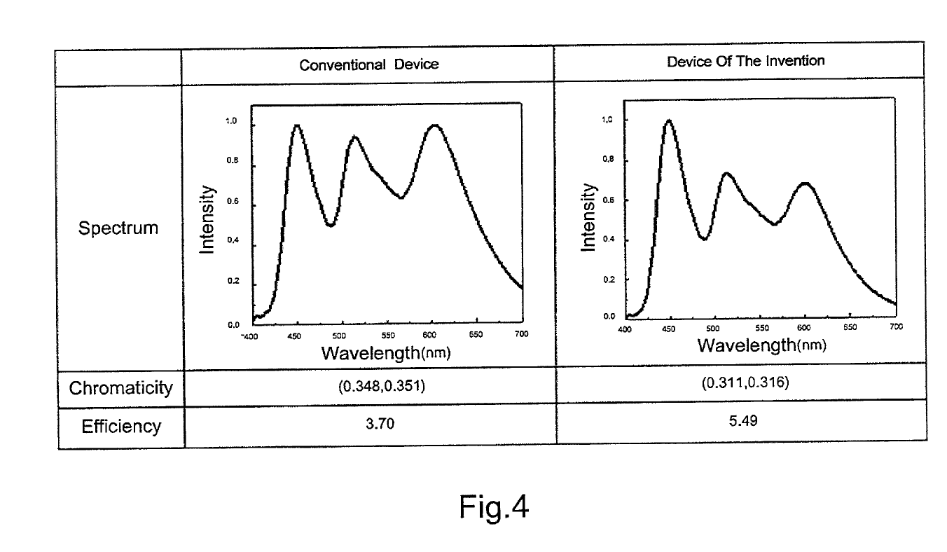

With further reference to FIG. 4, FIG. 4 is a chart comparing the white organic light-emitting device of the first embodiment in FIG. 1 with a conventional white organic light-emitting device, it can be seen that with the efficiency-enhancing layer 12 adjusting the characteristics and efficiency of the organic light-emitting unit 11, the white light emitted from the light-emitting unit 11 has a chromaticity coordinate of (0.311,0.316) which is relatively close to an ideal chromaticity coordinate of (0.31, 0.32) for a large-sized display panel, and the white organic light-emitting device has better light efficiency than the conventional white organic light-emitting device.

Furthermore, comparing with the conventional technology that directly adjusts the internal structure of a white organic light-emitting device, the present invention can adjust the light efficiency of an organic light-emitting unit 11 by simply adjusting the thickness of an efficiency-enhancing layer 12 disposed on the light-emitting surface of the organic light-emitting unit 11. Thus, the efficiency of the entire white organic light-emitting device can be improved without forming an optical micro-cavity with a complex reflection structure.

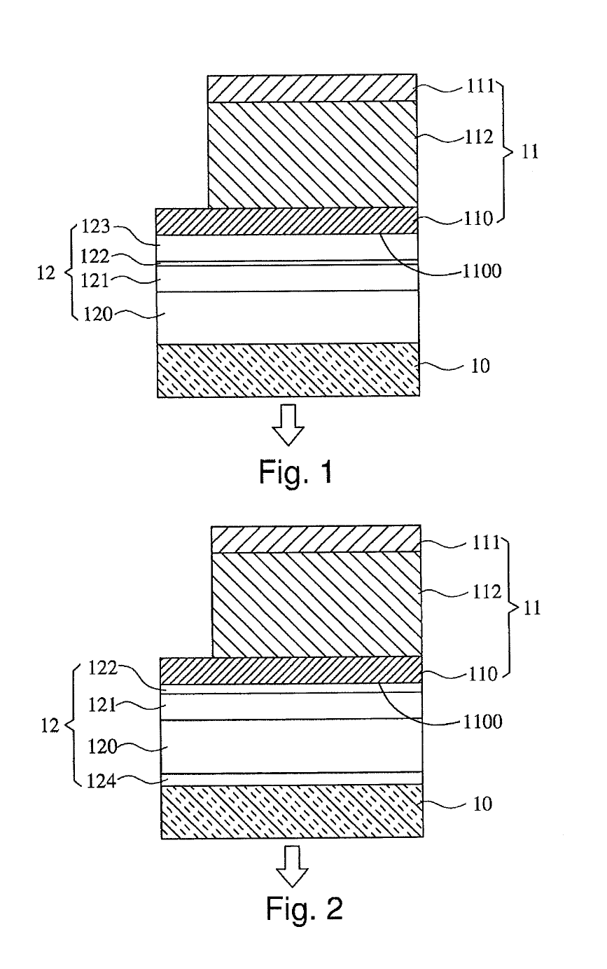

To meet different product needs, such as small-sized display panels, the thickness and materials of the efficiency-enhancing layer 12 may be relevantly changed. For example, with reference to FIG. 2, FIG. 2 is a schematic view of the structure of a white organic light-emitting device according to a second embodiment of the present invention. The embodiment in FIG. 2 differs from the embodiment 1 in that the efficiency-enhancing layer 12 in FIG. 2 is constructed by orderly laminating an indium tin oxide layer 124, a first silicon nitride layer 120, a silicon dioxide layer 121 and a second silicon dioxide layer 122 on the substrate 10 from bottom to top, wherein the indium tin oxide layer may for example have a thickness of 10 nanometers, the first silicon dioxide layer may for example have a thickness of 100 nanometers, the silicon nitride layer may for example have a thickness of 30 nanometers, and the second silicon dioxide layer may for example have a thickness of 6 nanometers.

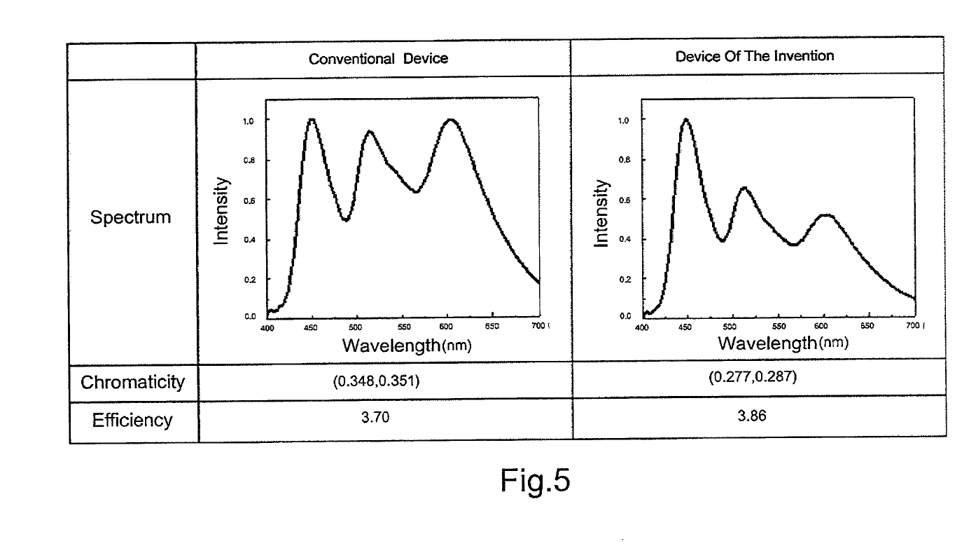

With further reference to FIG. 5, FIG. 5 is a chart comparing the white organic light-emitting device of the first embodiment in FIG. 2 with a conventional white organic light-emitting device, it can be seen that with the efficiency-enhancing layer 12 adjusting the characteristics and efficiency of the organic light-emitting unit 11, the white light emitted from the light-emitting unit 11 has a chromaticity coordinate of (0.277,0.287) which is relatively close to an ideal chromaticity coordinate of (0.28, 0.29) for a small-sized display panel, and the white organic light-emitting device has better light efficiency than the conventional white organic light-emitting device. Therefore, with the adjustment of the efficiency-enhancing layer 12, the white organic light-emitting device of the embodiment in FIG. 2 can be more applicable to small-sized display panels.

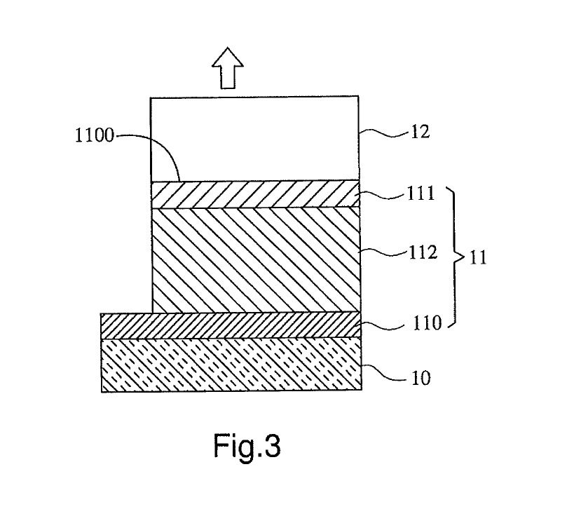

The efficiency-enhancing layer of the white organic light-emitting device of the present invention is not limited to be mounted only between the first electrode 110 and the substrate 10 as shown in FIG. 2 or FIG. 1. With reference to FIG. 3, FIG. 3 is a schematic view of the structure of a white organic light-emitting device according to a third embodiment of the present invention. The embodiment in FIG. 3 differs from the embodiment in FIG. 1 in that the first electrode 110 is an anode; the second electrode 111 is a cathode, and the organic light-emitting unit 11 has a light-emitting direction that is from the first electrode 110 to the second electrode 111. Therefore the light-emitting surface of the organic light-emitting unit 11 is located at a surface of the second electrode 111, and therefore the efficiency-enhancing layer 12 is disposed on the second electrode 111.

In conclusion, the present invention is mainly to form an efficiency-enhancing layer on a light-emitting surface of an organic light-emitting unit without affecting the internal structure of the organic light-emitting unit, so as to replace the traditional way of directly adjusting the structure of the organic material layers inside the organic light-emitting unit, which not only improve the chromaticity and efficiency of a white organic light-emitting device, but an objective of easily adjusting the efficiency of the white organic light-emitting device can also be achieved by adjusting the thickness of the efficiency-enhancing layer.

The present invention has been described with a preferred embodiment thereof and it is understood that many changes and modifications to the described embodiment can be carried out without departing from the scope and the spirit of the invention that is intended to be limited only by the appended claims.

1. A white organic light-emitting device comprising:
a substrate;
an organic light-emitting unit having a first electrode, a second electrode, an organic layer and a light-emitting surface, wherein the first electrode is disposed on the substrate and is an anode, the second electrode is disposed opposite to the first electrode and is a cathode, the organic layer is mounted between the first electrode and the second electrode, and the light-emitting surface is located at the first electrode; and
an efficiency-enhancing layer being mounted on the light-emitting surface of the organic light-emitting unit, wherein the efficiency-enhancing layer is disposed between the first electrode and the substrate; and the efficiency-enhancing layer is constructed by orderly laminating a first silicon dioxide layer, a first silicon nitride layer, a second silicon dioxide layer and a second silicon nitride layer on the substrate.

2. The white organic light-emitting device as claimed in claim 1, wherein each of the first silicon dioxide layer, the first silicon nitride layer, the second silicon dioxide layer and the second silicon nitride layer that construct the efficiency-enhancing layer has a thickness less than or equal to 1 micrometer.

3. A white organic light-emitting device comprising:
a substrate;
an organic light-emitting unit having a first electrode, a second electrode, an organic layer and a light-emitting surface, wherein the first electrode is disposed on the substrate, the second electrode is disposed opposite to the first electrode, the organic layer is mounted between the first electrode and the second electrode; and
an efficiency-enhancing layer being mounted on the light-emitting surface of the organic light-emitting unit.

4. The white organic light-emitting device as claimed in claim 3, wherein the first electrode is an anode, the second electrode is a cathode, the light-emitting surface of the organic light-emitting unit is located at the first electrode, and the efficiency-enhancing layer is disposed between the first electrode and the substrate.

5. The white organic light-emitting device as claimed in claim 3, wherein the first electrode is an anode; the second electrode is a cathode; the light-emitting surface of the organic light-emitting unit is located at the second electrode, and the efficiency-enhancing layer is disposed on the second electrode.

6. The white organic light-emitting device as claimed in claim 3, wherein the efficiency-enhancing layer includes at least one silicon dioxide layer and at least one silicon nitride layer.

7. The white organic light-emitting device as claimed in claim 6, wherein the efficiency-enhancing layer is constructed by orderly laminating a first silicon dioxide layer, a first silicon nitride layer, a second silicon dioxide layer and a second silicon nitride layer on the substrate.

8. The white organic light-emitting device as claimed in claim 6, wherein the efficiency-enhancing layer is constructed by orderly laminating an indium tin oxide layer, a silicon dioxide layer, a first silicon nitride layer and a second silicon dioxide layer on the substrate.

9. The white organic light-emitting device as claimed in claim 6, wherein each of the layers that construct the efficiency-enhancing layer has a thickness less than or equal to 1 micrometer.

10. The white organic light-emitting device as claimed in claim 7, wherein the first silicon dioxide layer has a thickness of 100 nanometers, the first silicon nitride layer has a thickness of 30 nanometers, the second silicon dioxide layer has a thickness of 1 nanometer, and the second silicon nitride layer has a thickness of 32 nanometers.

11. The white organic light-emitting device as claimed in claim 8, wherein the indium tin oxide layer has a thickness of 10 nanometers, the first silicon dioxide layer has a thickness of 100 nanometers, the silicon nitride layer has a thickness of 30 nanometers, and the second silicon dioxide layer has a thickness of 6 nanometers.

12. The white organic light-emitting device as claimed in claim 3, wherein the substrate is a glass substrate.
